(19) United States
(12) Patent Application Publication
(10) Pub. No.: US 2017/0023643 A1
(43) Pub. Date: Jan. 26, 2017

(54) HANDLER BASED AUTOMATED TESTING OF INTEGRATED CIRCUITS IN AN ELECTRONIC DEVICE

(71) Applicant: QUALCOMM Incorporated, San Diego, CA (US)

(72) Inventors: Rae-Ann Sobral LoCicero, La Jolla, CA (US); Keith Barry, San Diego, CA (US); Ibrahim Shaik, San Diego, CA (US); Karthik Ranganathan Vishwanathan, San Diego, CA (US); Sajjad Pagarkar, San Diego, CA (US)

(21) Appl. No.: 14/836,851

(22) Filed: Aug. 26, 2015

Related U.S. Application Data
(60) Provisional application No. 62/194,388, filed on Jul. 20, 2015.

(51) Int. Cl. G01R 31/28; G01R 1/04

(52) U.S. Cl. CPC G01R 31/2893; G01R 31/2887; G01R 1/0416

(57) ABSTRACT

A method and apparatus for testing electronic devices installed in a portable device. The apparatus incorporates a socket with receptacles for alignment pins, and an alignment plate with openings for the alignment pins. The holes for the alignment pins are matched to the socket receptacles, providing secure alignment. The spring loaded socket pin mates with at least one solder ball. The apparatus also includes a circuit card, which may be a modem test platform circuit card that has contacts that mate with the at least one solder ball. Other functions may be tested using other circuit card assemblies. A method of testing includes: installing the electronic device to be tested into a socket assembly, aligning the electronic device to be tested into the socket assembly; installing the socket assembly into a test apparatus, and testing the device.

### CLAIM OF PRIORITY UNDER 35 U.S.C. §119

The present application for patent claims priority to Provisional Application No. 62/194,388, entitled “HANDLER BASED AUTOMATED TESTING OF INTEGRATED CIRCUITS IN AN ELECTRONIC DEVICE” filed Jul. 20, 2015, and assigned to the assignee hereof and hereby expressly incorporated by reference herein.

### BACKGROUND

Field

The present disclosure relates generally to wireless communication system. More specifically the present disclosure is related to methods and apparatus for performing handler-based automated testing of integrated circuits (ICs) in a mobile device, such as a phone or tablet.

Background

As the use of mobile devices grows, so does the need to manufacture and test new devices in an efficient and cost-effective manner. Testing in the factory requires costly options on test equipment. This testing typically requires that the modem and other communication devices or circuits be thoroughly tested before delivery to a retailer, and eventually, an end user. In performing this testing automated handling devices assist in positioning and conducting the testing. In many cases, testing is performed on ICs prior to final assembly in a mobile phone or tablet, often using a socket.

Testing a chip or other device may require that the device be held in place, which may use a socket to provide access to test pins and related functions. Preferably, the socket used is a zero foot print socket used with an assembled mobile phone or tablet. A modem test platform (MTP) may be used in conjunction with a handler to perform this testing. A typical phone or MTP has a glass display case and traditional handlers and the sockets used with them may damage the MTP due to excessive pressure when the chip or tested device is inserted into or removed from a phone or tablet device.

In addition to pressure damage to the glass display case, a number of alignment problems may arise when a zero footprint socket is used. Due to the small size of ICs or chip devices, a small socket is needed, preferably one with a zero footprint to fit within the small dimensions. Alignment features may be needed to provide for accurate placement of the device when the handler drops the device to be tested into the socket. Moreover, custom pressure adjustments are needed to avoid damaging the MTP or phone glass display case.

There is a need in the art for methods and apparatus to improve zero footprint sockets for use with testing protocols to reduce or eliminate damage to the devices being tested.

### SUMMARY

Embodiments disclosed herein provide an apparatus for testing electronic devices. The apparatus incorporates a socket with receptacles for alignment pins, an alignment plate with openings for the alignment pins. The holes for the alignment pins are matched to the socket receptacles, providing secure alignment. The apparatus includes at least one alignment pin and at least one socket pin. The socket pin mates with at least one solder ball. The spring loaded socket pins ensure good contact during testing. The apparatus also includes a circuit card, which may be a modem test platform circuit card that has contacts that mate with the at least one solder ball. This modem test platform circuit card routes the test signals into the socket assembly. Other functions may be tested using other circuit card assemblies.

A further embodiment provides a method for testing an electronic device, wherein the electronic device has a form factor matching a completed portable electronic device. The method includes the steps of: installing an electronic device to be tested into a socket assembly; aligning the electronic device to be tested into the socket assembly; installing the socket assembly into a test apparatus; and testing the device.

A still further embodiment provides an apparatus for testing an electronic device. The apparatus includes: means for installing an electronic device to be tested into a socket assembly; means for aligning the electronic device to be tested into the socket assembly; means for installing the socket assembly into a test apparatus; and means for testing the electronic device.

### BRIEF DESCRIPTION OF THE DRAWINGS

FIG. 1 depicts a socket incorporating alignment features, in accordance with embodiments of the disclosure.

FIG. 2 illustrates a further embodiments of a socket incorporating alignment features in accordance with embodiments of the disclosure.

FIG. 3 is a flowchart of a method of testing using a socket incorporating alignment features in accordance with embodiments of the disclosure.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

As used in this application, the terms “component,” “module,” “system” and the like are intended to include a computer-related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

As used herein, the term “determining” encompasses a wide variety of actions and therefore, “determining” can include calculating, computing, processing, deriving, investigating, looking up (e.g., looking up in a table, a database or another data structure), ascertaining and the like. Also, “determining” can include resolving, selecting choosing, establishing, and the like.

The phrase “based on” does not mean “based only on,” unless expressly specified otherwise. In other words, the phrase “based on” describes both “based only on” and “based at least on.”

Moreover, the term “or” is intended to man an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The various illustrative logical blocks, modules, and circuits described in connection with the present disclosure may be implemented or performed with a general purpose processor, a digital signal processor (DSP), an application specific integrated circuit (ASIC), a field programmable gate array (FPGA), or other programmable logic device, discrete gate or transistor logic, discrete hardware components or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core or any other such configuration.

The steps of a method or algorithm described in connection with the present disclosure may be embodied directly in hardware, in a software module executed by a processor or in a combination of the two. A software module may reside in any form of storage medium that is known in the art. Some examples of storage media that may be used include RAM memory, flash memory, ROM memory, EPROM memory, EEPROM memory, registers, a hard disk, a removable disk, a CD-ROM, and so forth. A software module may comprise a single instruction, or many instructions, and may be distributed over several different code segments, among different programs and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in software, the functions may be stored as one or more instructions on a computer-readable medium. A computer-readable medium may be any available medium that can be accessed by a computer. By way of example, and not limitation, a computer-readable medium may comprise RAM, ROM, EEPROM, CD-ROM or other optical disk storage, magnetic disk storage, or other magnetic storage devices, or any other medium that can be used to carry or store desired program code in the form of instructions or data structures and that can be accessed by a computer. Disk and disc, as used herein, includes compact disk (CD), laser disk, optical disc, digital versatile disk (DVD), floppy disk, and Blu-ray® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

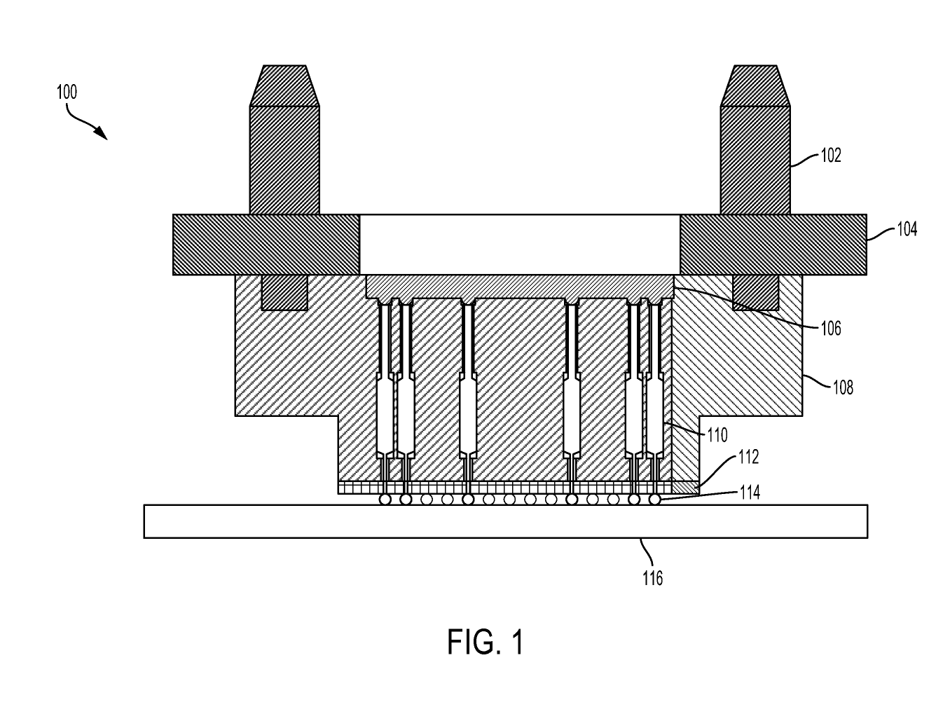

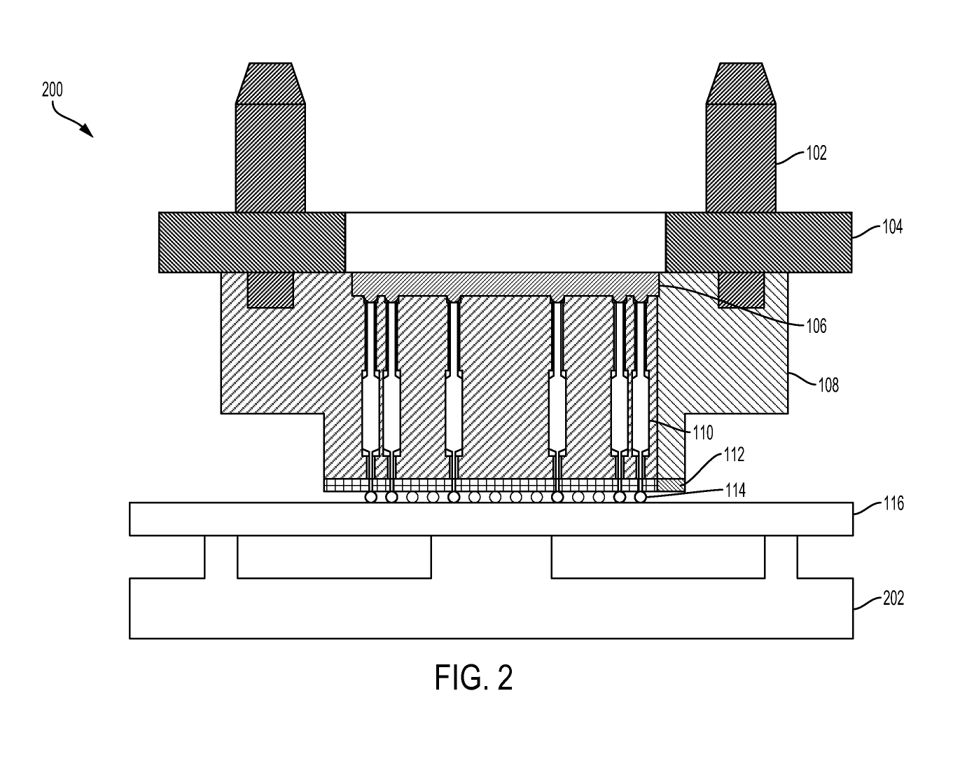

Further, it should be appreciated that modules and/or other appropriate means for performing the methods and techniques described herein, such as those illustrated by FIGS. 1 and 2, can be downloaded and/or otherwise obtained by a mobile device and/or base station as applicable. For example, such a device can be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a mobile device and/or base station can obtain the various methods upon coupling or providing the storage means to the device. Moreover, any other suitable technique for providing the methods and techniques described herein to a device can be utilized.

Furthermore, various aspects are described herein in connection with a terminal, which can be a wired terminal or a wireless terminal. A terminal can also be called a system, device, subscriber unit, subscriber station, mobile station, mobile, mobile device, remote station, remote terminal, access terminal, user terminal, communication device, user agent, user device, or user equipment (UE). A wireless terminal may be a cellular telephone, a satellite phone, a cordless telephone, a Session Initiation Protocol (SIP) phone, a wireless local loop (WLL) station, a personal digital assistant (PDA), a handheld device having wireless connection capability, a computing device, or other processing devices connected to a wireless modem. Moreover, various aspects are described herein in connection with a base station. A base station may be utilized for communicating with wireless terminal(s) and may also be referred to as an access point, a Node B, or some other terminology.

A method and apparatus for performing handler-based automated IC testing is provided by embodiments described herein. The methodology is designed for use in testing ICs already installed in a mobile phone or tablet, or similar device, however, the embodiments described herein are not limited in use to the scenarios described herein, but may be used to test a wide variety of ICs and devices.

Existing solutions require that the IC or chip to be tested be soldered to the MTP, mobile phone, or tablet device. This solution does not allow for automated testing. As a result, testing using this method required significant time and has no provision for removal and rework.

An alternate testing method currently in use provides for a large board, which may be known as a CDP to provide testing access. The CDP includes mechanical constraints and socket features to adapt to a variety of handlers. CDPs may provide handler friendly features that may facilitate testing. However, key drawbacks remain. Specifically, no automation of testing is possible, as every device must be fitted to the CDP and the CDP must be adapted to the specific handler to be used in testing. The CDP requires that a large “keep out” area, be provided. The “keep out” area is a margin needed to allow the handler and other test equipment access to the IC under test. The CDP is a non-form factor platform that does not lend itself to a wide variety of handler mechanisms.

Both of the test methodologies suffer from the drawback that neither can replicate the thermal constraints of actual operation. Neither method described above tests with the IC or chip installed in the end use device, and as a results, operates without being subjected to the thermal loading that occurs in the mobile phone or tablet. Other components, such as amplifiers and processors to generate heat that may flow through the heat sinks and the dies of the components. Testing with the IC separated from the end use device does not provide a complete understanding of the thermal loading that the completed device will experience. Thus, there is a need for a socket that incorporates alignment features and can handle the pressure encountered when testing in an end use device having a glass display.

FIG. 1 illustrates a socket design 100 that incorporates alignment features. The socket assembly 100 may be custom designed and may be designed to mate or match with existing handler features. The embodiment shown in FIG. 1 incorporates a socket support structure. Alignment pins 102 provide for handler to socket alignment and a lower portion of the alignment pins 102 provide for plate to socket alignment. The alignment pins 102 mate with an alignment plate 104, with the alignment pins 102 passing through receptacles on the alignment plate 104. The device or IC to be tested is placed in a recess 118 located within the socket 108. Solder pads or bumps on the IC placed within the socket recess 118 are placed in contact with the socket pins 110. These socket pins 110 may be spring loaded to ensure precise contact with the solder bumps on the IC to be tested. The socket pins extend fully through the socket 108 and are in contact with pads on a printed circuit board 114. The printed circuit board may be fabricated from a material such as FR4, or other suitable material. The opposite side of the printed circuit board may have solder balls 114 that complete the contact with the MTP circuit card assembly. These solder balls 114 are used in testing and the contacts allow high volume testing. The solder balls 114 are in contact with MTP circuit card assembly 116, which routes test signals through the socket assembly as part of a testing program.

FIG. 2 provides a further embodiment that incorporates the socket and alignment features of FIG. 1, and also incorporates a stiffener 202. The socket assembly 200 incorporates alignment pins 102. The alignment pins 102 pass through the alignment plate 104. The device or IC to be tested is placed in recess 118 located within socket 108. Solder pads or bumps on the device placed in recess 118 are in contact with socket pins 110. The socket pins extend completely through socket 108 and are in contact with pads on printed circuit board 114. The solder balls 114 are in contact with MTP circuit card assembly 116. MTP circuit card assembly 116 is further supported by stiffener 202. Stiffener 202 provides additional support during testing, preventing damage to the glass case or top of a completed mobile device.

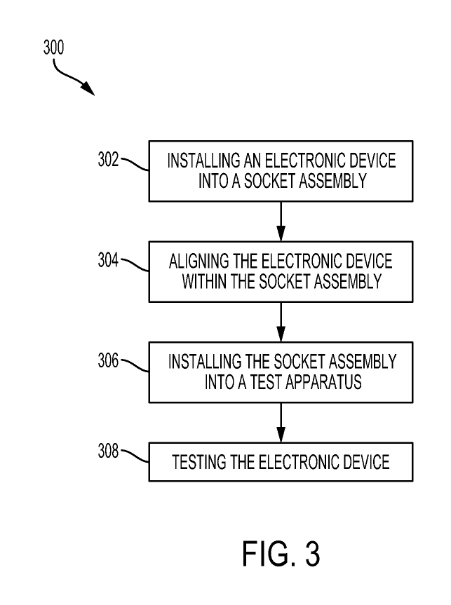

FIG. 3 is a flowchart of a method of handler-based automated testing of ICs installed in a phone, tablet, or other portable electronic device. The method 300 begins when the electronic device is installed into a socket assembly in step 302. The electronic device to be tested may be a modem or other chip within an assembled portable electronic device. The electronic device, and in particular, the modem or other chip to be tested is aligned within the socket assembly in step 304. The chip fits within the recess described above, with the spring pins of the socket assembly ensuring contact. The alignment pins ensure that the chip pads or bumps are in proper contact with the solder balls on the socket assembly. The socket assembly is then installed into a test apparatus in step 306. In step 308 testing of the electronic device is carried out. Placement of the device to be tested within the socket assembly may be carried out with an automated handler.

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An apparatus for testing electronic devices, comprising:
a socket having receptacles for alignment pins;
an alignment plate having openings for the alignment pins, wherein the holes for the alignment pins are matched to the socket receptacles;
at least one alignment pin, matched to the alignment plate and the socket; and
at least one socket pin, mating with at least one solder ball.

2. The apparatus of claim 1, further comprising:
a modem test platform circuit card assembly having contacts that mate with the at least one solder ball.

3. The apparatus of claim 1, further comprising:
a circuit card assembly having contacts that mate with the at least one solder ball.

4. The apparatus of claim 1, further comprising:
a stiffener in contact with the modem test platform circuit card assembly.

5. The apparatus of claim 1, wherein the socket is a zero footprint socket.

6. A method for testing an electronic device, comprising:
installing an electronic device to be tested into a socket assembly;
aligning the electronic device to be tested into the socket assembly;
installing the socket assembly into a test apparatus; and
testing the electronic device.

7. The method of claim 6, wherein the electronic device to be tested is an electronic chip installed within a form factor of a portable electronic device.

8. The method of claim 6, wherein the socket assembly is installed into a test apparatus by an automatic handler.

9. An apparatus for testing an electronic device, comprising:
means for installing an electronic device to be tested into a socket assembly;
means for aligning the electronic device to be tested into the socket assembly;
means for installing the socket assembly into a test apparatus; and
means for testing the electronic device.

10. The apparatus of claim 9, wherein the means for installing installs the electronic device to be tested into a zero footprint socket.

11. The apparatus of claim 10, wherein the means for installing the socket assembly into a test apparatus is an automatic handler.

12. The apparatus of claim 10, wherein the means for testing the electronic device interfaces with the socket assembly through a circuit card assembly.

13. The apparatus of claim 12, wherein the means for testing the electronic device tests a modem on the electronic device.
